(19) United States
(12) Patent Application Publication
(10) Pub. No.: US 2011/0254413 A1
(43) Pub. Date: Oct. 20, 2011

(54) CASING OF ELECTRONIC DEVICE AND MANUFACTURING METHOD THEREOF

(76) Inventor: Sheng Yu Tsai, Taipei (TW)

(21) Appl. No.: 13/086,758

(22) Filed: Apr. 14, 2011

(30) Foreign Application Priority Data
Apr. 16, 2010 (CN) 201010148606.1

(51) Int. Cl. H05K 5/02; B29C 45/14

(52) U.S. Cl. 312/223.1; 264/279

(57) ABSTRACT

A casing of an electronic device and a manufacture method thereof are disclosed. A thin film with a protecting film is provided in a mold. Plastic is injected into the mold from an injection inlet of the mold to form the casing, and the location of the protecting film corresponds to that of the injection inlet. After the casing is formed, the protecting film and the plastic are molded integratedly.

### CROSS REFERENCE TO RELATED APPLICATIONS

This Non-provisional application claims priority under 35 U.S.C. §119(a) on Patent Application No(s). 201010148606.1 filed in People's Republic of China on Apr. 16, 2010, the entire contents of which are hereby incorporated by reference.

### BACKGROUND OF THE INVENTION

1. Field of Invention

The invention relates to a casing and a manufacture method thereof and, more particularly, to a casing of an electronic device protecting film and a manufacture method thereof.

2. Related Art

With the development of the science and technology, various kinds of consumptive electronic products are more and more popular. Meanwhile, the consumers have higher requirements on the exterior appearance, the manufacture technology of a conventional plastic appearance cannot satisfy the consumers.

For example, in the conventional plastic injection molding, the surface of the product is processed after the injection molding. Consequently, it is difficult to achieve three-dimension (3D) multi-color printing, and when the different parts of the product have different colors, the product cannot be integrally formed. Different parts can only be assembled after they are injection molded individually, which consumes more cost and time.

As a result, the advanced plastic surface manufacture technology is gradually used in the manufacture industry to meet domestic and international environmental standards instead. Among that, the free-spray in-mold decoration (IMD) technology is the most popular. IMD technology has many advantages makes IMD technology more applicable. The advantages are like environmental protection, scratch resisting, low cost, high tension, high efficiency, 3D molding, and special color effect which the conventional plastic injection technology does not have. For example, the IMD technology is adapted to certain high value—added plastic products, such as the electronic products and the automobile parts, especially for casings of the mobile phone, MP3 player and other electronic devices or the ornaments inside or outside a car.

In different IMD technologies, the in-mold film (IMF) injection molding is an extremely advanced one. FIGS. 1A to 1E are flowcharts showing a conventional IMF injection molding method. First, as shown in FIG. 1A, a layer of a thin film 1 is formed in a mold 2. In practical usage, the thin film 1 may be made of polycarbonate (PC) or polyester, which is not limited herein.

Then, as shown in FIG. 1B, a decoration layer 3 (such as ink-printed) is printed on the thin film 1. After the decoration layer 3 is dried, plastic P is injected into the mold 2 through an injection inlet 20 of the mold 2 to integrate the plastic P and the thin film 1, as shown in FIG. 1C. When the injection molding is accomplished, as shown in FIG. 1D, the thin film 1 is combined with the injected plastic P. Since the decoration layer 3 is sandwiched between the thin film 1 and the plastic P, patterns of the decoration layer 3 are protected and not wear off. Moreover, before the injection molding, the thin film 1 is three-dimensionally molded in advance, and then placed in the mold 2 for the injection molding. Thus, injection moldings for various kinds of three-dimensional decorations can be obtained, which cannot be achieved by the conventional plastic injection molding method.

Since the plastic P is injected to the mold 2 through the injection inlet 20 of the mold 2, the patterns on the decoration layer 3 often been washed out in a position corresponding to the injection inlet 20, as shown in FIG. 1E. Conventionally, the solution to solve the patterns being washed out is to repeat the printing procedures several times to form the decoration layer 3 with sufficient thickness and strength. However, it leads with time and labor consuming in printing and drying the decoration layer 3 during the plastic injection molding, and the competitiveness of the products is affected in the market by the increased cost.

Furthermore, when the mold 2 is removed in advance during the plastic injection molding, a shadow trace might be formed on the end product in a position K (as shown in FIG. 1D) corresponding to the injection inlet 20; however, when the mold 2 is removed when the plastic injection molding process is completed, a protrusion on the end product is formed in a position corresponding to the injection inlet 20. Even though the protrusion can be cut off, a small uneven portion may leave at the position K. Both the shadow trace and the uneven place affect the product outlook, especially when the end product is with light color.

### SUMMARY OF THE INVENTION

The invention provides a method for manufacturing a casing of an electronic device.

In an embodiment of the invention, a method for manufacturing a casing of an electronic device is provided. In the embodiment, the method for manufacturing the casing of the electronic device includes the following steps: providing a thin film with a protecting film in a mold; injecting plastic to the mold from an injection inlet of the mold to form the casing. The position of the protecting film corresponds to that of the injection inlet, where the protecting film and the plastic are integrated.

In an embodiment, the protecting film includes a base film and an adhesive, and the adhesive is between the thin film and the base film. The component of the base film includes polyimide, and the component of the adhesive includes acrylic ester copolymer, rosin ester resin and Polyethylene (PE). The ratios of the polyimide, the acrylic ester copolymer, the rosin ester resin and the PE are 40% to 60%, 15% to 35%, 5% to 25% and 5% to 15%, respectively, and in an embodiment, the ratios are 50%, 25%, 15% and 9%, which is, however, not limited herein.

Compared with the conventional technology, the method for manufacturing the casing of the electronic device in an embodiment is not only to avoid a washing out phenomenon effectively by using a protecting film, but also to integrate the protecting film on the thin film and the thermoplastic polymer gradually in the process of injecting the thermoplastic polymer to the mold. According to an embodiment, forming a decoration layer by printing many times as the conventional technology is not a necessary process. Thus, the time for printing and drying in the plastic injection molding process and the human resource cost are saved greatly, and the market competitiveness is improved. Moreover, the method for manufacturing the casing of the electronic device in an embodiment avoids leaving a shadow trace or an uneven place at the position of the plastic injection mold corresponding to the injection inlet, and improves the beauty of the product outlook.

These and other features, aspects and advantages of the present invention will become better understood with regard to the following description, appended claims, and accompanying drawings.

### BRIEF DESCRIPTION OF THE DRAWINGS

FIGS. 1A to 1E are flowcharts showing a conventional in-mold film (IMF) injection molding method;

FIG. 2 is a flowchart showing a method for manufacturing a casing of an electronic device of an embodiment;

FIG. 3 is a flowchart showing a method for manufacturing a casing of an electronic device in an embodiment;

FIGS. 4A to 4E are schematic views showing a method for manufacturing a casing of an electronic device in FIG. 3; and

FIGS. 5A to 5E are schematic views showing a method for manufacturing a casing of an electronic device in an embodiment.

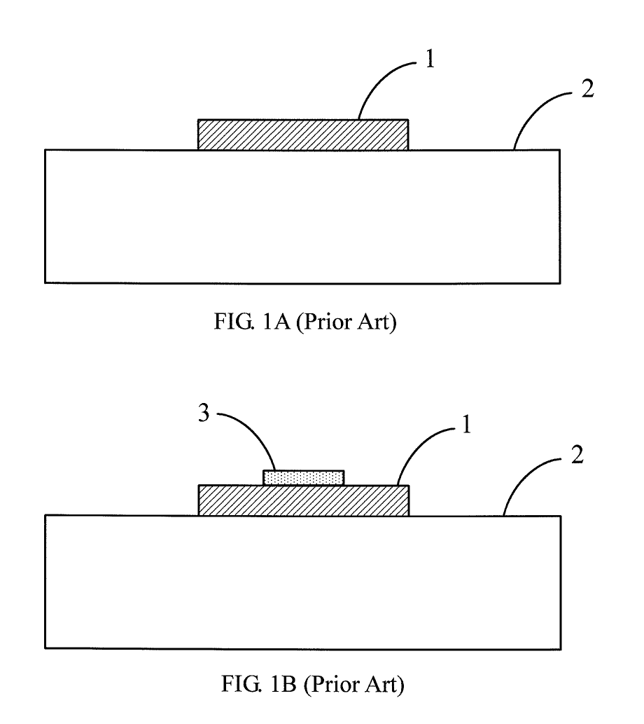

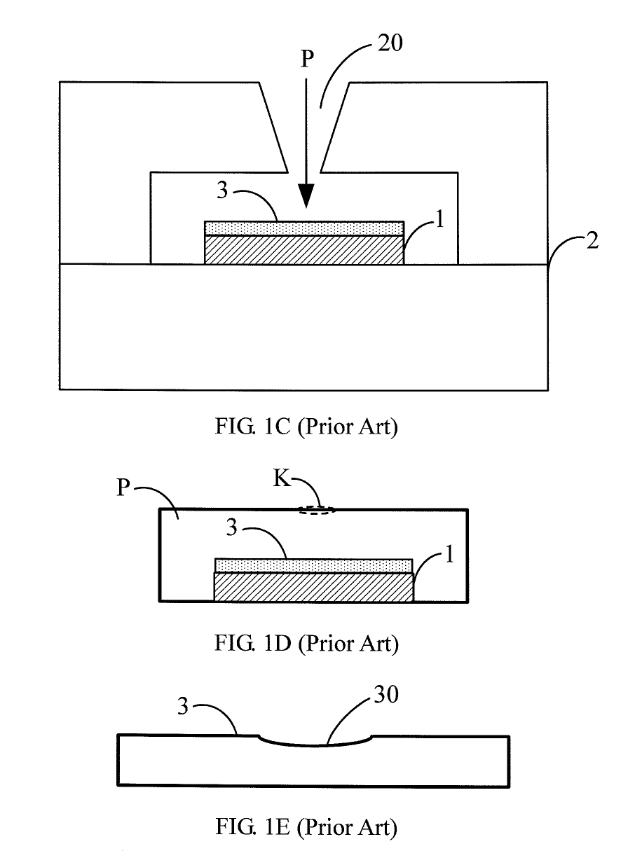

### DETAILED DESCRIPTION OF THE INVENTION

In an embodiment, the method for manufacturing the casing of the electronic device is an IMF injection molding method, which is not limited herein.

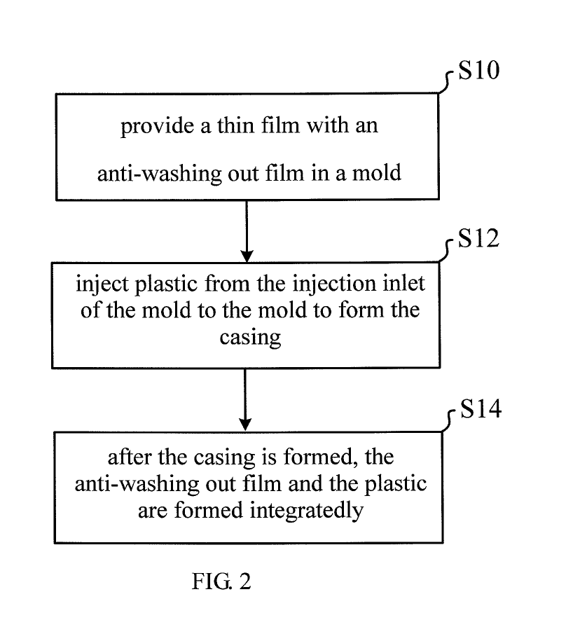

FIG. 2 is a flowchart showing a method for manufacturing a casing of an electronic device in an embodiment of the invention. Referring to FIG. 2, the method for manufacturing the casing of the electronic device in the embodiment includes the following steps. First, in step S10, a thin film with a protecting film is disposed in a mold. In an embodiment, the thin film with the protecting film may be obtained by attaching the protecting film to the thin film. The area and the size of the protecting film attached to the thin film are not limited, which is determined according to practical requirements.

Generally, the protecting film is mainly used to protect the patterns being washed out during plastic injection, and thus the area of the attached protecting film is defined based on the injection inlet area of the mold. For example, the injection inlet area of the mold corresponding to the protecting film is cylindrical, when the diameter of the cylindrical injection inlet is large, the sticking area of the protecting film should be large correspondingly to prevent the patterns being washed out. Conversely, when the diameter of the cylindrical injection inlet area is small, the area of the protecting film can be small to save material cost.

Practically, the protecting film includes a base film and an adhesive, and the adhesive is disposed between the thin film and the base film. In one embodiment, the component of the base film includes polyimide, the component of the adhesive includes acrylic ester copolymer, rosin ester resin and Polyethylene (PE), is not, however, limited herein. Moreover, in one embodiment, the ratios of the polyimide, the acrylic ester copolymer, the rosin ester resin and the PE are ranged from 40% to 60%, 15% to 35%, 5% to 25%, and 5% to 15%, respectively. In one embodiment, the ratios of the polyimide, the acrylic ester copolymer, the rosin ester resin and the PE may be 50%, 25%, 15% and 9%, which is not, however, limited herein.

After the thin film with the protecting film is disposed in the mold, step S12 is executed to inject the plastic from the injection inlet to the mold to form the casing, wherein the position of the attached protecting film corresponds to the position of the injection inlet to avoid the pattern being washed-out. In practical application, the plastic is a thermoplastic polymer material; however, the type of plastic is not limited herein.

In the process of injecting the plastic to the mold, the protecting film attached to the thin film are combined with the plastic gradually. After the casing is formed, the protecting film and the plastic are integrated (Step S14). However, in practical application, the protecting film may not be completely combined with the plastic, a part of the protecting film may remain uncombined without any impact on the casing. Practically, the ratios of the component of the protecting film can be adjusted according to the requirement to integrate the protecting film and the plastic completely. Furthermore, before the plastic is injected to the mold, the thin film may be three-dimensionally shaped according to the mold or the casing product in advance, which is not limited herein.

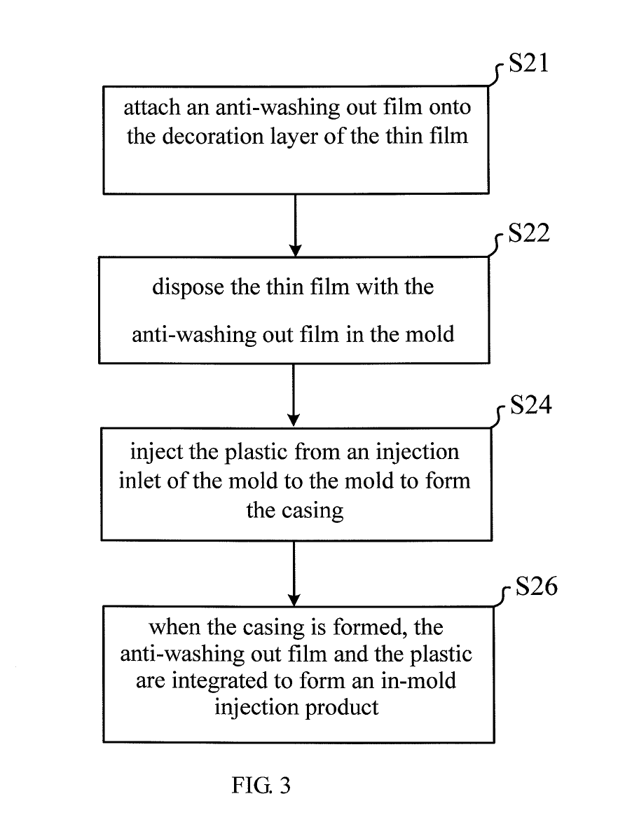

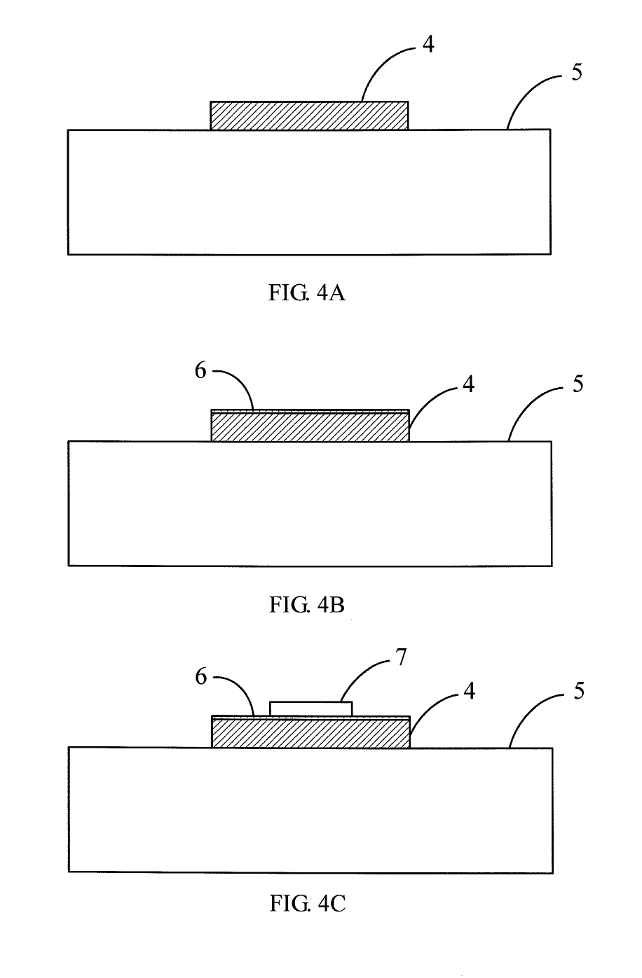

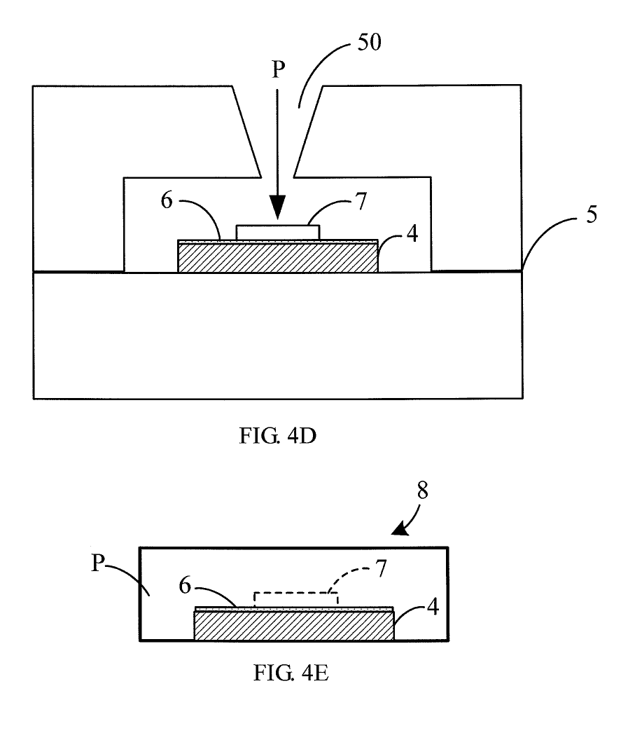

FIG. 3 is a flowchart showing the method for manufacturing the casing of the electronic device in one embodiment. FIGS. 4A to 4E are schematic views showing the method for manufacturing the casing of the electronic device in the embodiment. As shown in FIGS. 4A and 4B, the thin film 4 including the decoration layer 6 is disposed in the mold 5.

In practical application, the material of the decoration layer may be ink, Polyethylene (PE), Polypropylene (PP), polyethylene terephthalate (PET), polybutylene terephthalate (PBT), polymethylmethacrylate (PMMA), Polyvinylchloride (PVC), polyurethane (PU) and polyamide (PA), which is not limited herein.

As shown in FIG. 3, first, at Step S21, a protecting film is attached onto the decoration layer of the thin film. As shown in FIG. 4C, the protecting film 7 is attached to an area of the decoration layer 6.

Then, performing Step S22 and the following Step S24, the thin film with the protecting film is disposed in the mold, and then the plastic injected is injected from an injection inlet into the mold to form the casing. As shown in FIG. 4D, the thin film 4 along with the attached protecting film 7 is disposed in the mold 5, and then, the plastic P is injected from the injection inlet 50 of the mold 5 to the mold 5 to form the casing.

In the process of injecting the plastic P to the mold 5, the protecting film 7 on the thin film 4 is combined with the plastic P gradually. When the casing is formed, as shown in FIG. 4E, the protecting film 7 and the plastic P are integrated to form an in-mold injection product 8 (Step S26). The decoration layer 6 is between the plastic P and the thin film 4 and being well protected, the patterns with colors can be maintained without wear for a long time.

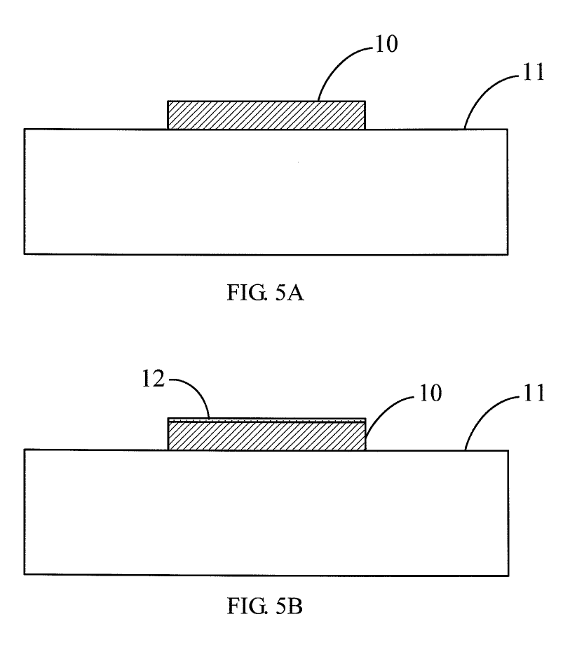

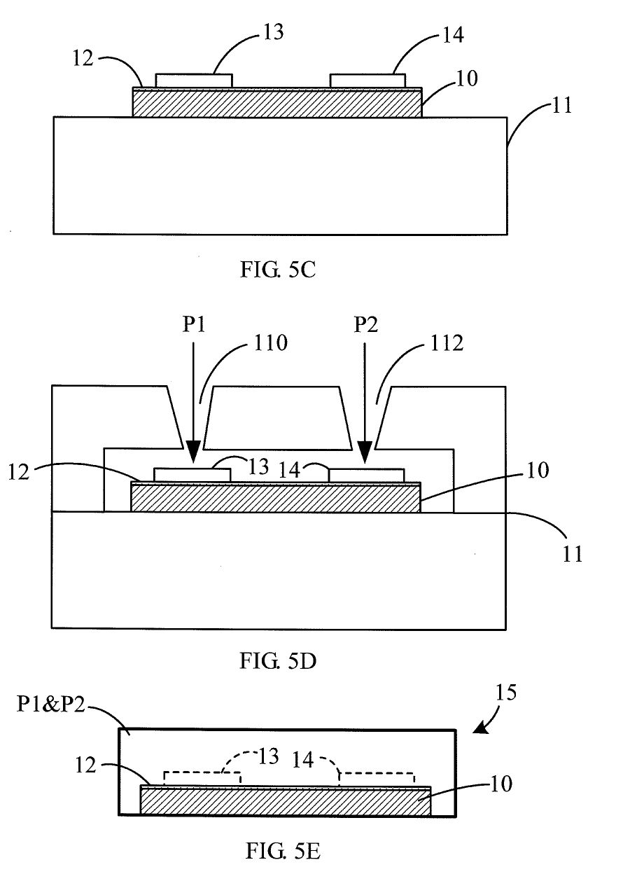

The number and the position of the injection inlets of the mold in the mentioned embodiment are not limited, and can be determined according to the practical requirement. In an embodiment, the mold includes two injection inlets. FIGS. 5A to 5E are schematic views showing a method for manufacturing a casing of an electronic device in another embodiment.

First, as shown in FIGS. 5A and 5B, the thin film 10 including the decoration layer 12 is disposed in the mold 11. Then, as shown in FIG. 5C, the protecting films 13 and 14 are attached to two different areas of the decoration layer 6, respectively. As shown in FIG. 5D, the thin film 10 along with the protecting films 13 and 14 is disposed in the mold 11, and the positions of the protecting films 13 and 14 correspond to that of the two injection inlets 110 and 112 of the mold 11. The plastic P1 and P2 are injected from the injection inlets 110 and 112 to the mold 11, respectively, to form the casing. Practically, the plastic P1 and P2 are the same thermoplastic polymer material, but are not limited herein.

In the process of injecting the plastic P1 and P2 to the mold 11, the protecting films 13 and 14 of the thin film 10 and the plastic P1 and P2 are combined gradually. After the casing is formed, as shown in FIG. 5E, when the protecting films 13 and 14 and the plastic P1 and P2 are combined completely, the plastic P1 and P2 and the thin film 10 are integrated to form an in-mold injection product 15. The decoration layer 12 is disposed between the plastic P1 and P2 and the thin film 10. Since the decoration layer 12 is well protected between the plastic P1 and P2 and the thin film 10, the patterns with colors can be well maintained without wear in a long time.

In practical application, the protecting films 13 and 14 and the plastic P1 and P2 may not be combined completely, with a part remaining, but the remained protecting film has no negative influence on the plastic P1 and P2 or the final in-mold injection product 15. Practically, the ratios of the component of the protecting films 13 and 14 can be regulated according to the requirement, so as to combine the protecting films 13 and 14 and the plastic P1 and P2 completely. Moreover, before the plastic P1 and P2 are injected to the mold 11, the thin film 10 may be three-dimensionally molded in advance, which is not limited herein.

Compared with the conventional technology, with the method for manufacturing the casing of the electronic device, the washing out phenomenon is avoided effectively via the protecting film. Furthermore, the protecting film attached to the thin film is gradually combined with the thermoplastic polymer in the process of injecting the thermoplastic polymer to the mold. Thus, it does not need to form the decoration layer by several-times printing as the conventional technology, as a result, time and labor for printing and drying the whole plastic injection molding are saved greatly, which improves the market competitiveness.

The casing of the electronic device using the manufacture method in the embodiments includes a casing body which may be made of plastic, polyimide, acrylic ester copolymer, rosin ester resin and PE. The ratios of the polyimide, the acrylic ester copolymer, the rosin ester resin and the PE are ranged from 40% to 60%, from 15% to 35%, from 5% to 25%, and from 5% to 15%, respectively, and the ratios may be 50%, 25%, 15% and 9%, respectively. According to the method manufacturing the casing of the electronic device, a shadow trace or an uneven place on the plastic injection mold corresponding to the injection inlet is avoided, and thus the appearance is more beautiful.

Although the present invention has been described in considerable detail with reference to certain preferred embodiments thereof, the disclosure is not for limiting the scope of the invention. Persons having ordinary skill in the art may make various modifications and changes without departing from the scope. Therefore, the scope of the appended claims should not be limited to the description of the preferred embodiments described above.

What is claimed is:

1. A method for manufacturing a casing of an electronic device, comprising:
providing a thin film along with a protecting film in a mold; and
injecting plastic to the mold from an injection inlet of the mold to form the casing;
wherein the position of the protecting film corresponds to that of the injection inlet, and after the casing is formed, the protecting film and the plastic are integrated.

2. The method for manufacturing the casing of the electronic device according to claim 1, wherein the protecting film comprises a base film and an adhesive between the thin film and the base film.

3. The method for manufacturing the casing of the electronic device according to claim 2, wherein the component of the base film comprises polyimide, and the component of the adhesive includes acrylic ester copolymer, rosin ester resin and polyethylene (PE).

4. The method for manufacturing the casing of the electronic device according to claim 3, wherein the ratios of the polyimide, the acrylic ester copolymer, the rosin ester resin and the PE are ranged from 40% to 60%, 15% to 35%, 5% to 25%, and 5% to 15%, respectively.

5. The method for manufacturing the casing of the electronic device according to claim 1, wherein the thin film comprises a decoration layer.

6. The method for manufacturing the casing of the electronic device according to claim 5, wherein the material of the decoration layer comprises ink, PE, polypropylene (PP), polyethylene terephthalate (PET), polybutylene terephthalate (PBT), polymethylmethacrylate (PMMA), polyvinylchloride (PVC), polyurethane (PU) and polyamide (PA).

7. The method for manufacturing the casing of the electronic device according to claim 5, wherein when the plastic and the thin film are integrated, the decoration layer is between the plastic and the thin film.

8. A casing of an electronic device, comprising:
a casing body made of plastic, polyimide, acrylic ester copolymer, rosin ester resin and polyethylene (PE).

9. The casing of the electronic device according to claim 8, wherein the ratios of the polyimide, the acrylic ester copolymer, and the rosin ester resin and the PE are ranged from 40% to 60%, 15% to 35%, 5% to 25%, and 5% to 15%, respectively.
